(19) United States
(12) Patent Application Publication
(10) Pub. No.: US 2015/0098116 A1
(43) Pub. Date: Apr. 9, 2015

(54) FACSIMILE MACHINE

(71) Applicant: Samsung Electronics Co., Ltd., Suwon-si (KR)

(72) Inventor: Jeong Baek LEE, Suwon-si (KR)

(21) Appl. No.: 14/459,641

(22) Filed: Aug. 14, 2014

(30) Foreign Application Priority Data
Oct. 7, 2013 (KR) 10-2013-0119013

(51) Int. Cl. H04N 1/00; H05K 1/02

(52) U.S. Cl. CPC H04N 1/0083; H04N 1/00095; H05K 1/0231; H04N 2201/0093; H04N 2201/0094; H04N 2201/3278
USPC 358/442

(57) ABSTRACT

A facsimile machine capable of preventing a communication clock signal from being emitted in the form of electromagnetic waves during communication, for example, transmission/reception of facsimile data includes a line terminal provided for coupling with a line cord and connected with a common line and a first signal line, an external device terminal provided for coupling with an external device and connected with the common line and a second signal line, a switch to perform switching between the first and second signal lines, and a first electromagnetic wave prevention unit provided on the common line and the second signal line to discharge electromagnetic waves generated on the common line and the second signal line.

### CROSS-REFERENCE TO RELATED APPLICATIONS

This application claims the priority benefit of Korean Patent Application No. 10-2013-0119013, filed on Oct. 7, 2013 in the Korean Intellectual Property Office, the disclosure of which is incorporated herein by reference.

### BACKGROUND

1. Field

The following description relates to a facsimile machine having a line terminal provided for coupling with a line cord and an external device terminal provided for coupling with an external device, a method of controlling the same, and an image forming apparatus having a facsimile function.

2. Description of the Related Art

A facsimile machine is a device that converts an image of a picture, text, a diagram, etc. into an electrical signal and transmits the converted electrical signal over a communication line, and restores a received electrical signal into an original image. In this manner, the facsimile machine necessitates use of a communication line for transmission and reception of electrical signals, which may be a public switched telephone line, generally called a telephone line.

To this end, the facsimile machine has a line terminal provided for coupling with a line cord, and an external device terminal provided for coupling with an external device (for example, a telephone). The line cord coupled to the line terminal enables facsimile data to be transmitted and received over the telephone line. The external device coupled to the external device terminal enables a call to be made via the line cord, using, for example, a telephone.

When the facsimile machine performs communication, because a communication clock signal is emitted in the form of electromagnetic waves, the standard approach for anti-electromagnetic waves may not be easily satisfied.

### SUMMARY

Therefore, it is an aspect of the present disclosure to provide a facsimile machine capable of preventing a communication clock signal from being emitted in the form of electromagnetic waves during communication, for example, transmission/reception of facsimile data.

Additional aspects of the disclosure will be set forth in part in the description which follows and, in part, will be obvious from the description, or may be learned by practice of the invention.

In accordance with an aspect of the present disclosure, a facsimile machine includes a line terminal provided for coupling with a line cord and connected with a common line and a first signal line, an external device terminal provided for coupling with an external device and connected with the common line and a second signal line, a switch to perform switching between the first and second signal lines, and a first electromagnetic wave prevention unit provided on the common line and the second signal line to discharge electromagnetic waves generated on the common line and the second signal line.

The first electromagnetic wave prevention unit may be provided to discharge the electromagnetic waves to ground.

The first electromagnetic wave prevention unit may be provided on the common line and the second signal line between the switch and the external device terminal.

The first electromagnetic wave prevention unit may include a plurality of capacitors.

The first electromagnetic wave prevention unit may include a first capacitor connected between the second signal line and ground, and a second capacitor connected between the common line and the ground.

A sum of capacitances of the first and second capacitors may be equal to or less than 1 nF.

A sum of capacitances of the first and second capacitors may be in a range of 100 pF to 1 nF.

In accordance with an aspect of the present disclosure, a facsimile machine includes a line terminal provided for coupling with a line cord and connected with a common line and a first signal line, an external device terminal provided for coupling with an external device and connected with the common line and a second signal line, a switch to perform switching between the first and second signal lines, a first electromagnetic wave prevention unit provided on the common line and the second signal line to discharge electromagnetic waves generated on the common line and the second signal line, and a second electromagnetic wave prevention unit provided on the common line and the first signal line to discharge electromagnetic waves generated on the common line and the first signal line.

The first and second electromagnetic wave prevention units may be provided to discharge the electromagnetic waves to ground.

The first electromagnetic wave prevention unit may be provided on the common line and the second signal line between the switch and the external device terminal.

The first electromagnetic wave prevention unit may include a plurality of capacitors.

The first electromagnetic wave prevention unit may include a first capacitor connected between the second signal line and ground, and a second capacitor connected between the common line and the ground.

A sum of capacitances of the first and second capacitors may be equal to or less than 1 nF.

A sum of capacitances of the first and second capacitors may be in a range of 100 pF to 1 nF.

The facsimile machine may further include a rectifier, and the first electromagnetic wave prevention unit may be provided on the common line and the first signal line between the rectifier and the switch.

The second electromagnetic wave prevention unit may include a plurality of capacitors.

The second electromagnetic wave prevention unit may include a third capacitor connected between the first signal line and ground, and a fourth capacitor connected between the common line and the ground.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a perspective diagram of a facsimile machine according to an embodiment of the present disclosure;

FIG. 2 is a diagram showing a communication connection state of the facsimile machine of FIG. 1;

FIG. 3 is a block diagram showing a control system of the facsimile machine, according to an embodiment of the present disclosure;

FIG. 4 is a circuit diagram of a line connector of the facsimile machine, according to an embodiment of the present disclosure;

FIG. 5 is a circuit diagram of a line connector of the facsimile machine, according to an embodiment of the present disclosure; and

FIG. 6 is a diagram showing the effect of a first electromagnetic wave prevention unit and a second electromagnetic wave prevention unit of the facsimile machine, according to an embodiment of the present disclosure.

### DETAILED DESCRIPTION

Reference will now be made in detail to the embodiments of the present disclosure, examples of which are illustrated in the accompanying drawings, wherein like reference numerals refer to like elements throughout.

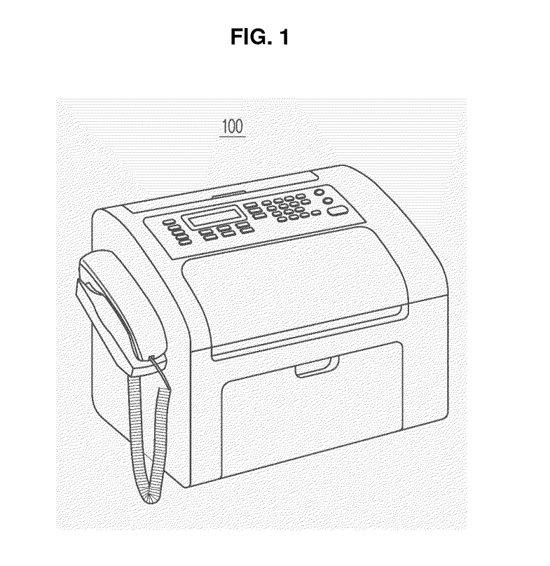

FIG. 1 is a perspective diagram of a facsimile machine 100 according to an embodiment of the present disclosure. The present disclosure may be applied to a multifunction printer having a facsimile function, as well as the single-item facsimile machine 100 shown in FIG. 1. The single-item facsimile machine 100 or a facsimile function part of the multifunction printer converts an image of a picture, text, a diagram, etc. into an electrical signal and transmits the converted electrical signal over a communication line, and restores a received electrical signal into an original image. In this manner, the facsimile machine 100 or the facsimile function part necessitates use of a communication line for transmission and reception of electrical signals, which may be a public switched telephone line, generally called a telephone line.

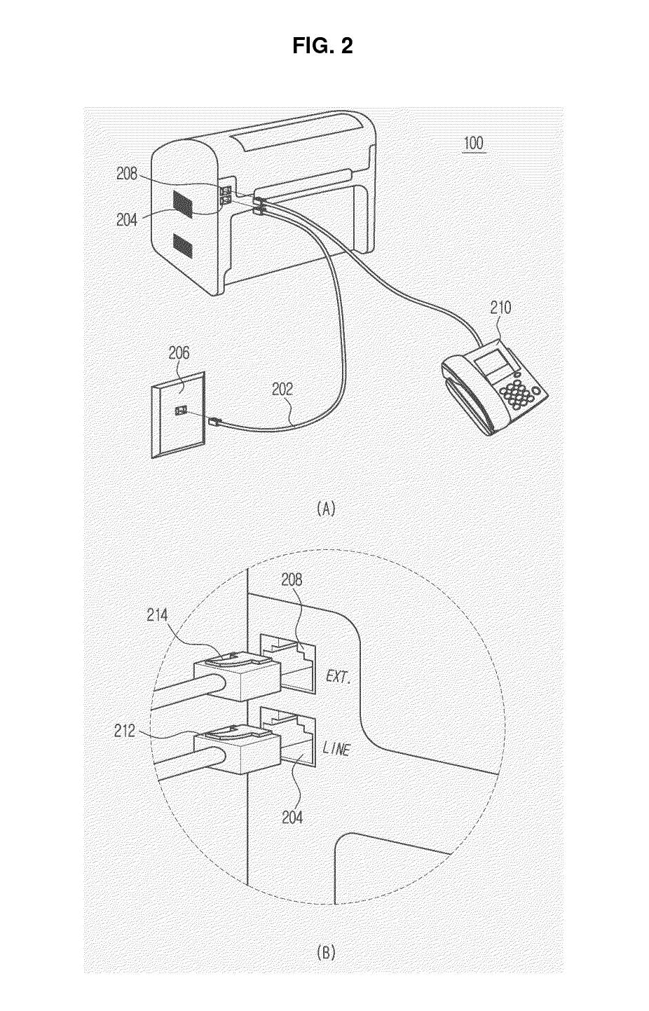

FIG. 2 is a diagram showing a communication connection state of the facsimile machine 100 of FIG. 1. In the case where the facsimile machine 100 uses the telephone line as the communication line, a line cord 202 is connected between a line terminal 204 of the facsimile machine 100 and a socket (a socket of a telephone network) 206 on a wall, as shown in FIG. 2(A), such that the facsimile machine 100 performs communication over the telephone line. In addition, an external device, such as a telephone 210, is connected to an external device terminal 208 of the facsimile machine 100. That is, a line jack 212 of the line cord 202 should be inserted into the line terminal 204 of the facsimile machine 100, and an external device jack 214 of the telephone 210 should be inserted into the external device terminal 208 of the facsimile machine 100, as shown in FIG. 2(B). To this end, a mark indicating that the telephone line should be connected, such as “LINE”, is provided at the line terminal 204 of the facsimile machine 100, and a mark indicating that the external device such as the telephone 210 should be connected, such as “EXT.”, is provided at the external device terminal 208 of the facsimile machine 100. However, the user may misunderstand or incorrectly recognize such guide marks, thereby inserting the external device jack 214 of the telephone 210 into the line terminal 204 of the facsimile machine 100 and inserting the line jack 212 of the line cord 202 into the external device terminal 208 of the facsimile machine 100.

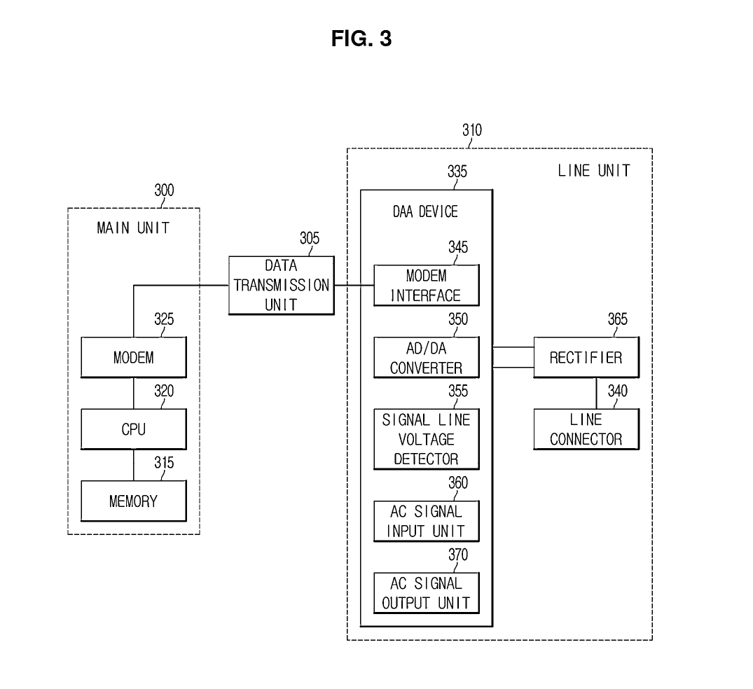

FIG. 3 is a block diagram showing a control system of the facsimile machine 100, according to an embodiment of the present disclosure. The control system of the facsimile machine 100 includes a main unit 300, a data transmission unit 305, and a line unit 310, as shown in FIG. 3.

The main unit 300 includes a memory 315, a controller (for example, a central processing unit (CPU)) 320, and a modem 325. The line unit 310 includes a data access arrangement (DAA) device 335, a rectifier 365, and a line connector 340. The DAA device 335 includes a modem interface 345, an analog-to-digital/digital-to-analog (AD/DA) converter 350, a signal line voltage detector 355, an alternating current (AC) signal input unit 360, and an AC signal output unit 370.

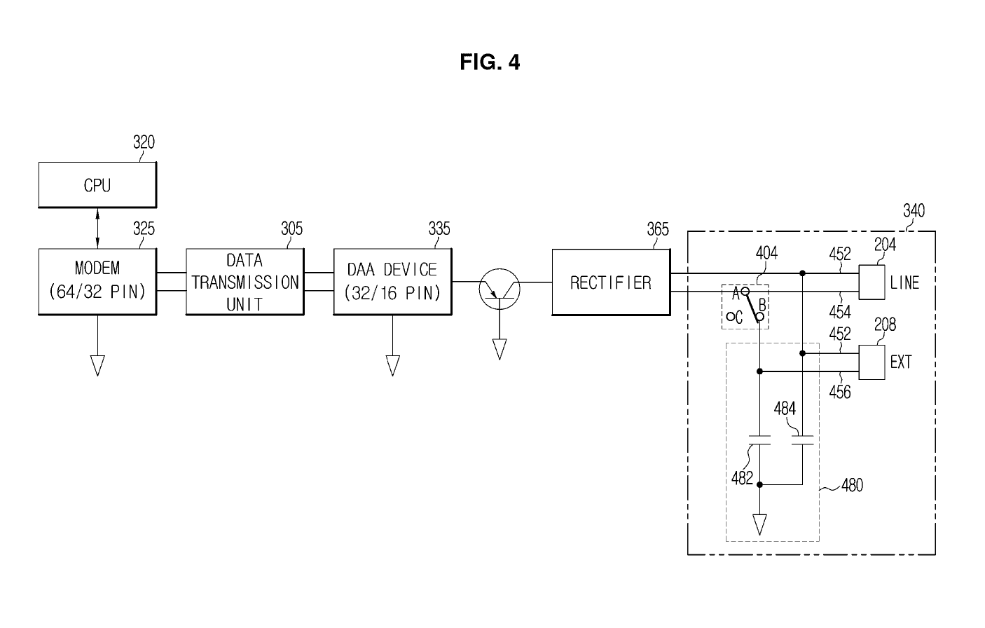

Operation of the facsimile machine 100 will hereinafter be described in terms of facsimile data reception. An AC signal from a telephone network through the line connector 340 is input to the AC signal input unit 360 through the rectifier 365 and then converted into a digital signal by the AD/DA converter 350. The rectifier 365 allows constant direct current (DC) to flow through signal lines (see a common line 452, a first signal line 454, and a second signal line 456 of FIG. 4).

The converted digital signal is re-converted into a data signal of a predetermined format through the modem interface 345. The data transmission unit 305 transmits the converted data signal, a clock signal, etc. to the main unit 300. The transmitted signals are transferred to the modem 325. The modem 325 extracts certain data from the data signal and the extracted data is stored in the memory 315 through the controller 320. The data stored in the memory 315 is then printed on recording paper.

The AC signal output unit 370 functions to amplify an output AC signal and send the amplified AC signal to the telephone network. The signal line voltage detector 355 detects a voltage at the line terminal 204 and a voltage at the external device terminal 208 and transfers the voltage detection results to the controller 320, and the controller 320 determines a line connection state based on the voltage detection results. Here, determining the line connection state means determining whether the line jack 212 of the line cord 202 has been inserted into the line terminal 204 of the facsimile machine 100 or determining whether the external device jack 214 of the telephone 210 has been inserted into the external device terminal 208 of the facsimile machine 100. In general, a switch of the telephone network supplies a DC voltage of 48V over the telephone line. In this regard, when the line cord 202 is connected, the DC voltage of 48V is detected at a corresponding terminal. The controller 320 may determine which one of the line cord 202 and the external device (telephone 210) has been connected, based on which one of the DC voltage of 48V and a DC voltage of 0V is detected at the line terminal 204 or the external device terminal 208. In the case where the DC voltage of 48V is detected at any one terminal, the controller 320 may determine that the line cord 202 has been connected to that terminal. Conversely, in the case where the DC voltage of 0V is detected at any one terminal, the controller 320 may determine that a line other than the line cord 202 (for example, a cable of the telephone) has been connected to that line.

FIG. 4 is a circuit diagram of the line connector 340 of the facsimile machine 100, according to an embodiment of the present disclosure. As shown in FIG. 4, the line connector 340 includes the line terminal 204 and the external device terminal 208 described previously with reference to FIG. 2, and a switch 404 to communicably and electrically connect one of the line terminal 204 and the external device terminal 208 to the DAA device 335. The line terminal 204 and the external device terminal 208 share the common line 452, and are communicably and electrically connected to the DAA device 335 through the rectifier 365 respectively via the first and second signal lines 454 and 456. The first signal line 454 is connected to the line terminal 204, and the second signal line 456 is connected to the external device terminal 208. The switch 404 includes a contact A, contact B, and contact C. The contact A is connected to the first signal line 454 extending from the line terminal 204, and the contact B is connected to the second signal line 456 extending from the external device terminal 208. The contact C is neither connected to the first signal line 454 nor to the second signal line 456. For transmission/reception of a facsimile signal, the controller 320 connects the contacts A and C such that the signal is transferred to the DAA device 335 through the rectifier 365 only via the first signal line 454 and the common line 452. In addition, for transmission/reception of an external device signal, the controller 320 connects the contacts A and B such that the signal is transferred to the DAA device 335 via the second signal line 456.

In a conventional scheme using an analog modem, emission of electromagnetic waves from a main board was not a problem because the modem and a line interface communicate with each other without using an additional clock signal. However, because a DAA device having a digitized integrated circuit has been used instead of the conventional line interface having an analog individual device circuit, a clock signal having a frequency of 4 MHz is used for communication between a modem and the DAA device. Due to use of the clock signal, a signal line of the line terminal 204 or the external device terminal 208 may function as an antenna and thus noise (electromagnetic waves) may be emitted from the line terminal 204 or the external device terminal 208.

In order to prevent the emission of electromagnetic waves, the facsimile machine 100 according to the embodiment includes a first electromagnetic wave prevention unit 480 on the common line 452 and the second signal line 456 to discharge electromagnetic waves, which could be emitted via the second signal line 456, to ground.

The first electromagnetic wave prevention unit 480 is provided on the second signal line 456 and the common line 452 between the switch 404 and the external device terminal 208. The first electromagnetic wave prevention unit 480 includes a first capacitor 482 and a second capacitor 484. The first capacitor 482 is connected between the second signal line 456 and ground, and the second capacitor 484 is connected between the common line 452 and ground. When the contacts A and B of the switch 404 are connected, the first electromagnetic wave prevention unit 480 discharges electromagnetic waves, which are generated from the rectifier 365 on the second signal line 456 and the common line 452, to ground such that the electromagnetic waves are not emitted from the line terminal 204 or the external device terminal 208. A sum of capacitances of the first and second capacitors 482 and 484 included in the first electromagnetic wave prevention unit 480 is from approximately 100 pF to approximately 1 nF. If the capacitance of the first electromagnetic wave prevention unit 480 exceeds 1 nF, communication characteristics of the second signal line 456 may be changed and thus the capacitance of the first electromagnetic wave prevention unit 480 may be set to be equal to or less than 1 nF.

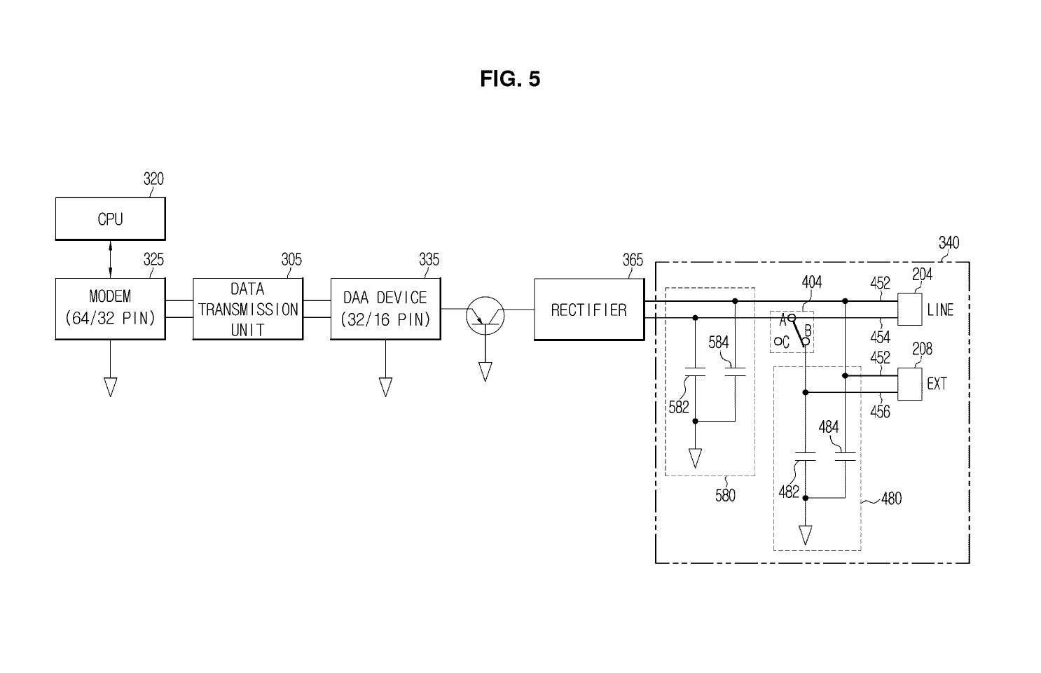

FIG. 5 is a circuit diagram of the line connector 340 of the facsimile machine 100, according to an embodiment of the present disclosure. As shown in FIG. 5, the line connector 340 includes the line terminal 204 and the external device terminal 208 described previously with reference to FIG. 2, and a switch 404 to communicably and electrically connect one of the line terminal 204 and the external device terminal 208 to the DAA device 335. The line terminal 204 and the external device terminal 208 share the common line 452, and are communicably and electrically connected to the DAA device 335 through the rectifier 365 respectively via the first and second signal lines 454 and 456. The first signal line 454 is connected to the line terminal 204, and the second signal line 456 is connected to the external device terminal 208. The switch 404 includes a contact A, contact B, and contact C. The contact A is connected to the first signal line 454 extending from the line terminal 204, and the contact B is connected to the second signal line 456 extending from the external device terminal 208. The contact C is neither connected to the first signal line 454 nor to the second signal line 456. For transmission/reception of a facsimile signal, the controller 320 connects the contacts A and C such that the signal is transferred to the DAA device 335 through the rectifier 365 only via the first signal line 454 and the common line 452. In addition, for transmission/reception of an external device signal, the controller 320 connects the contacts A and B such that the signal is transferred to the DAA device 335 via the second signal line 456.

In a conventional scheme using an analog modem, emission of electromagnetic waves from a main board was not a problem because the modem and a line interface communicate with each other without using an additional clock signal. However, because a DAA device having a digitized integrated circuit has been used instead of the conventional line interface having an analog individual device circuit, a clock signal having a frequency of 4 MHz is used for communication between a modem and the DAA device. Due to use of the clock signal, a signal line of the line terminal 204 or the external device terminal 208 may function as an antenna and thus noise (electromagnetic waves) may be emitted from the line terminal 204 or the external device terminal 208.

In order to prevent the emission of electromagnetic waves, the facsimile machine 100 according to the current embodiment includes a first electromagnetic wave prevention unit 480 on the common line 452 and the second signal line 456 to discharge electromagnetic waves, which could be emitted via the second signal line 456, to ground. In addition, according to the current embodiment, a second electromagnetic wave prevention unit 580 is further provided on the common line 452 and the first signal line 454 to discharge electromagnetic waves, which could be emitted via the first signal line 454, to ground. The second electromagnetic wave prevention unit 580 may also be used to protect the circuit from surge current flowing through the common line 452 and the first signal line 454, or the common line 452 and the second signal line 456.

The first electromagnetic wave prevention unit 480 is provided on the second signal line 456 and the common line 452 between the switch 404 and the external device terminal 208. The first electromagnetic wave prevention unit 480 includes a first capacitor 482 and a second capacitor 484. The first capacitor 482 is connected between the second signal line 456 and ground, and the second capacitor 484 is connected between the common line 452 and ground. When the contacts A and B of the switch 404 are connected, the first electromagnetic wave prevention unit 480 discharges electromagnetic waves, which are generated from the rectifier 365 on the second signal line 456 and the common line 452, to ground such that the electromagnetic waves are not emitted from the line terminal 204 or the external device terminal 208. A sum of capacitances of the first and second capacitors 482 and 484 included in the first electromagnetic wave prevention unit 480 is from approximately 100 pF to approximately 1nF. If the capacitance of the first electromagnetic wave prevention unit 480 exceeds 1 nF, communication characteristics of the second signal line 456 may be changed and thus the capacitance of the first electromagnetic wave prevention unit 480 may be set to be equal to or less than 1 nF.

The second electromagnetic wave prevention unit 580 is provided on the first signal line 454 and the common line 452 between the rectifier 365 and the switch 404. The second electromagnetic wave prevention unit 580 includes a third capacitor 582 and a fourth capacitor 584. The third capacitor 582 is connected between the first signal line 454 and ground, and the fourth capacitor 584 is connected between the common line 452 and ground. The second electromagnetic wave prevention unit 580 discharges electromagnetic waves, which are generated from the rectifier 365 on the second signal line 456 and the common line 452, to ground such that the electromagnetic waves are not emitted from the line terminal 204 or the external device terminal 208. Electromagnetic waves not discharged by the second electromagnetic wave prevention unit 580 may be discharged by the above-described first electromagnetic wave prevention unit 480 to ground. The second electromagnetic wave prevention unit 580 may also be used to protect the circuit from surge current flowing through the common line 452 and the first signal line 454, or the common line 452 and the second signal line 456.

When the size of the DAA device 335 is reduced from 32 pins to 16 pins, a chip is reduced in size and thus power supply and ground lines of a circuit inside the chip are also reduced in size. If the size is reduced as described above, power states of the VCC and GND lines of the circuit inside the chip are not stable and thus are easily influenced by disturbance. That is, because the DAA device 335 is produced as an integrated circuit and thus an integrated circuit insulating scheme is used, noise of a signal line may not be easily blocked. In addition, due to size reduction of the DAA device 335, a chip is reduced in size, a variety of lines such as power supply, ground, and signal lines are reduced in width, and thus blocking of noise becomes more difficult. Accordingly, in an anti-electromagnetic wave scheme to prevent electromagnetic waves by forming a Y-capacitor between a ground line of the modem 325 and a ground line of the DAA device 335, restrictions due to size reduction of the DAA device 335 should be further considered and, even worse, the anti-electromagnetic wave scheme itself using a Y-capacitor can cause noise. As such, the anti-electromagnetic wave scheme using a Y-capacitor may not be easily realized. However, if the first and second electromagnetic wave prevention units 480 and 580 according to the embodiment are used, even when the DAA device 335 is reduced in size and thus an anti-electromagnetic wave function is weakened, emission of electromagnetic waves from the line terminal 204 or the external device terminal 208 may be prevented due to operations of the first and second electromagnetic wave prevention units 480 and 580 and, additionally, the degree of freedom in designing the DAA device 335 and the modem 325 may be increased.

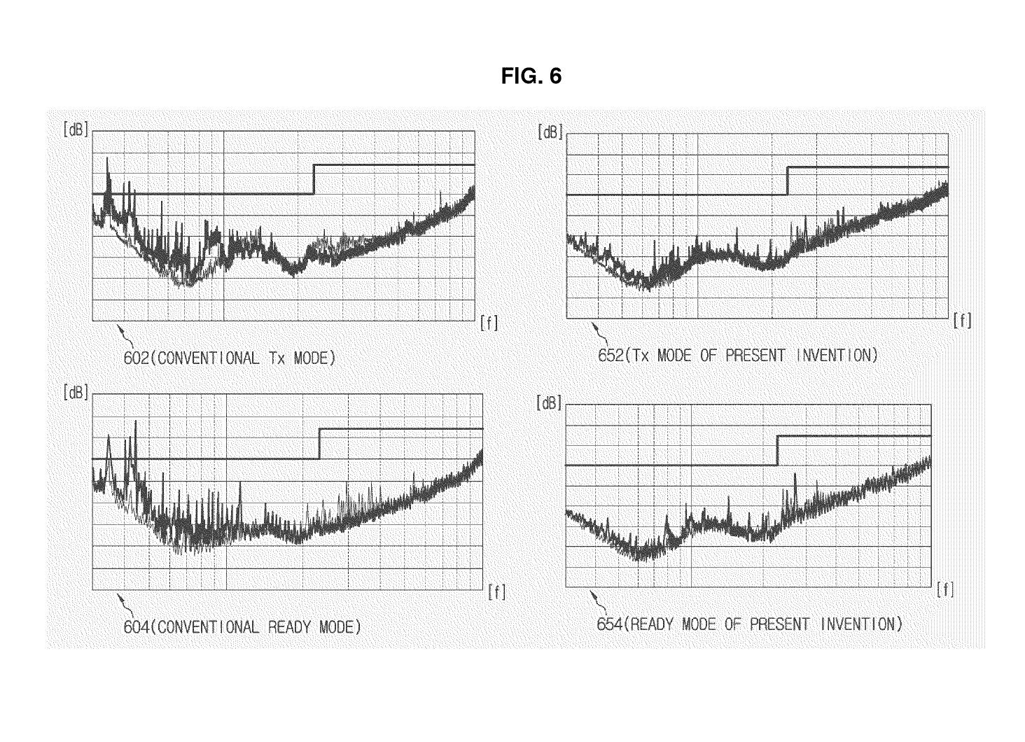

FIG. 6 is a diagram showing the effect of the first and second electromagnetic wave prevention units 480 and 580 of the facsimile machine 100, according to an embodiment of the present disclosure. In FIG. 6, a graph 602 shows electromagnetic waves measured in a transmission (Tx) mode when the present disclosure is not applied, and a graph 604 shows electromagnetic waves measured in a ready mode when the present disclosure is not applied. A graph 652 shows electromagnetic waves measured in a Tx mode while the first and second electromagnetic wave prevention units 480 and 580 according to an embodiment of the present disclosure are used, and a graph 654 shows electromagnetic waves measured in a ready mode while the first and second electromagnetic wave prevention units 480 and 580 according to an embodiment of the present disclosure are used. As shown in FIG. 6, compared to the electromagnetic waves in the left two graphs 602 and 604 to which the present disclosure is not applied, the electromagnetic waves in the right two graphs 652 and 654 to which the present disclosure is applied are greatly reduced.

As is apparent from the above description, a facsimile machine according to the present disclosure may prevent a communication clock signal from being emitted in the form of electromagnetic waves during communication, for example, transmission/reception of facsimile data, and thus may satisfy the standard for anti-electromagnetic waves.

Although a few embodiments of the present disclosure have been shown and described, it would be appreciated by those skilled in the art that changes may be made in these embodiments without departing from the principles and spirit of the invention, the scope of which is defined in the claims and their equivalents.

What is claimed is:

1. A facsimile machine comprising:
a line terminal configured to couple with a line cord and connected with a common line and a first signal line;
an external device terminal configured to couple with an external device and connected with the common line and a second signal line;
a switch configured to switch between the first and second signal lines; and
a first electromagnetic wave prevention unit coupled to the common line and the second signal line configured to discharge electromagnetic waves generated on the common line and the second signal line.

2. The facsimile machine according to claim 1, wherein the first electromagnetic wave prevention unit discharges the electromagnetic waves to ground.

3. The facsimile machine according to claim 1, wherein the first electromagnetic wave prevention unit is coupled to the common line and the second signal line between the switch and the external device terminal.

4. The facsimile machine according to claim 1, wherein the first electromagnetic wave prevention unit comprises a plurality of capacitors.

5. The facsimile machine according to claim 1, wherein the first electromagnetic wave prevention unit comprises:
a first capacitor connected between the second signal line and ground; and
a second capacitor connected between the common line and the ground.

6. The facsimile machine according to claim 5, wherein a sum of capacitances of the first and second capacitors is equal to or less than 1 nF.

7. The facsimile machine according to claim 5, wherein a sum of capacitances of the first and second capacitors is from 100 pF to 1 nF.

8. A facsimile machine comprising:
a line terminal configured to couple with a line cord and connected with a common line and a first signal line;
an external device terminal configured to couple with an external device and connected with the common line and a second signal line;
a switch configured to switch between the first and second signal lines;
a first electromagnetic wave prevention unit coupled to the common line and the second signal line configured to discharge electromagnetic waves generated on the common line and the second signal line; and
a second electromagnetic wave prevention unit coupled to the common line and the first signal line configured to discharge electromagnetic waves generated on the common line and the first signal line.

9. The facsimile machine according to claim 8, wherein the first and second electromagnetic wave prevention units discharge the electromagnetic waves to ground.

10. The facsimile machine according to claim 8, wherein the first electromagnetic wave prevention unit is coupled to the common line and the second signal line between the switch and the external device terminal.

11. The facsimile machine according to claim 8, wherein the first electromagnetic wave prevention unit comprises a plurality of capacitors.

12. The facsimile machine according to claim 8, wherein the first electromagnetic wave prevention unit comprises:
a first capacitor connected between the second signal line and ground; and
a second capacitor connected between the common line and the ground.

13. The facsimile machine according to claim 12, wherein a sum of capacitances of the first and second capacitors is equal to or less than 1 nF.

14. The facsimile machine according to claim 12, wherein a sum of capacitances of the first and second capacitors is from 100 pF to 1 nF.

15. The facsimile machine according to claim 8, further comprising a rectifier,
wherein the first electromagnetic wave prevention unit is coupled to the common line and the first signal line between the rectifier and the switch.

16. The facsimile machine according to claim 8, wherein the second electromagnetic wave prevention unit comprises a plurality of capacitors.

17. The facsimile machine according to claim 8, wherein the second electromagnetic wave prevention unit comprises:
a third capacitor connected between the first signal line and ground; and
a fourth capacitor connected between the common line and the ground.

18. A facsimile machine comprising:
a connector configured to couple with a telephone communication line;
a signal line which communicates with the connector;
a common line which communicates with the connector; and
an electromagnetic wave preventer which communicates with the common line and the signal line to discharge electromagnetic waves generated on the common line and the signal line.
